(19) United States
(12) Patent Application Publication
(10) Pub. No.: US 2026/0123353 A1
(43) Pub. Date: Apr. 30, 2026

(54) MULTI-AXIS STAGE APPARATUS, WAFER BONDING METHOD, AND WAFER BONDING APPARATUS USING THE SAME

(71) Applicant: SEMES CO., LTD., Chungcheongnam-do (KR)

(72) Inventors: Kyoungho EO, Chungcheongnam-do (KR); Dongwook LIM, Chungcheongnam-do (KR)

(21) Appl. No.: 19/303,428

(22) Filed: Aug. 19, 2025

(30) Foreign Application Priority Data
Oct. 24, 2024 (KR) 10-2024-0147011

(51) Int. Cl. H01L 21/687; H01L 21/68; H10D 88/00

(52) U.S. Cl. CPC H10P 72/7624; H10D 88/01; H10P 72/53

(57) ABSTRACT

The present disclosure relates to a multi-axis stage apparatus capable of significantly improving the precision of wafer bonding. The apparatus may include a base portion, a first driving device configured to vertically move at least a portion thereof in a third axis direction by a first distance with respect to the base portion, a second driving device formed on the first driving device and configured to vertically move at least a portion thereof in the third axis direction by a second distance, and an alignment stage connected to the second driving device and configured to align a first wafer chuck holding a first wafer such that the first wafer can be vertically moved in the third axis direction by a distance equal to the sum of the first and second distances.

### CROSS REFERENCE TO RELATED APPLICATIONS

This application claims the benefit under 35 U.S. C. § 119 of Korean Patent Application No. 10-2024-0147011, filed on Oct. 24, 2024, the disclosure of which is hereby incorporated by reference in its entirety.

### BACKGROUND

### 1. Field of the Disclosure

The present disclosure relates to a multi-axis stage apparatus, a wafer bonding method using the same, and a wafer bonding apparatus. More particularly, the present disclosure pertains to a multi-axis stage apparatus capable of significantly improving the precision of wafer bonding, a wafer bonding method using the same, and a wafer bonding apparatus.

### 2. Description of the Related Art

A semiconductor manufacturing process is a process for manufacturing semiconductor devices on a substrate (e.g., a wafer), and may include processes such as exposure, deposition, etching, ion implantation, and cleaning.

To perform each of these manufacturing processes, semiconductor manufacturing equipment corresponding to each process is provided in a clean room of a semiconductor manufacturing facility, and process treatment on the substrate loaded into the semiconductor manufacturing equipment may be performed.

Meanwhile, to produce semiconductor products having a stacked structure of a plurality of substrates, such as High Bandwidth Memory (HBM), a wafer-to-wafer (W2W) bonding process for bonding wafers together has been developed. This conventional wafer bonding process is a process for bonding multiple wafers together and may largely include a process of aligning the wafers with each other and a process of bringing the wafers into close contact with each other.

However, in conventional wafer bonding apparatuses, in order to secure a sufficient stroke, the wafer is moved up and down in the Z-axis direction using a single actuator with precision on the order of micrometers or millimeters. Therefore, it has been mechanically very difficult to achieve high precision on the order of nanometers. Even if the precision of the single actuator is improved, there are many problems, such as a significant decrease in the speed of vertical movement.

In addition, in conventional wafer bonding apparatuses, during the multi-axis movement and rotation of the wafer chuck along the X-axis, Y-axis, Z-axis, first rotational axis, second rotational axis, and theta axis (third rotational axis), mechanical errors or component damage can easily occur due to the use of ball joints or the like. Furthermore, mechanical deformation or thermal deformation can easily occur due to load, among other problems.

### SUMMARY OF THE DISCLOSURE

The present disclosure has been devised to solve the above-described problems and other issues. It is an object of the present disclosure to provide a multi-axis stage apparatus, a wafer bonding method using the same, and a wafer bonding apparatus, which can significantly improve the precision of wafer bonding by employing two actuators with different precision levels for vertical movement in the Z-axis direction. However, the above-mentioned object is merely illustrative and does not limit the scope of the present disclosure.

According to an aspect of the present disclosure, a multi-axis stage apparatus includes a base portion, a first driving device provided on the base portion and configured to move at least a portion thereof in a third axis direction by a first distance with respect to the base portion, a second driving device provided on the first driving device and configured to move at least a portion thereof in the third axis direction by a second distance with respect to the first driving device, and an alignment stage connected to the second driving device and configured to move a first wafer in the third axis direction by a distance equal to the sum of the first distance and the second distance, and to align a first wafer chuck that holds the first wafer in place.

According to the present disclosure, the first driving device may be configured to roughly move the first wafer in the third axis direction by the first distance, which is relatively longer than the second distance, and the second driving device may be configured to precisely move the first wafer in the third axis direction by the second distance, which is relatively shorter than the first distance.

According to the present disclosure, the first driving device may move the first wafer up and down with relatively low precision, on the order of micrometers or millimeters or greater, by using a ball screw or a lead screw, and the second driving device may move the first wafer up and down with high precision, on the order of nanometers or less, by using a first voice coil motor (VCM) or a piezoelectric element.

According to the present disclosure, the first driving device may include a driving motor provided on the base portion and configured to rotate a screw shaft, and a movable frame including a nut member configured to move vertically by the rotation of the screw shaft.

According to the present disclosure, the driving motor may be a direct drive (DD) motor that directly drives the screw shaft, and the movable frame may have the nut member threadably engaged with the screw shaft at a central portion thereof.

According to the present disclosure, the second driving device may include a plurality of first voice coil motors (VCMs) isometrically arranged around the nut member on the movable frame, a plurality of movable stages precisely driven up and down by the first voice coil motors, and a plurality of flexure joints formed on the movable stages and providing multi-axis degrees of freedom.

According to the present disclosure, the first voice coil motors may be arranged in a quadrilateral or triangular configuration around the nut member on the movable frame, so that the first wafer can be rotated about the first rotational axis or the second rotational axis.

According to the present disclosure, the second driving device may further include at least one load compensation device, which is formed between the base portion and the movable stage and disperses the load acting on the flexure joints to prevent heat generation from the first voice coil motors.

According to the present disclosure, the load compensation device may include a slider formed on an outer portion of the movable stage and at least partially composed of a first magnetic material, a stator fixed to the base portion and at least partially composed of a second magnetic material that interacts with the first magnetic material via attraction or repulsion, and a guide bearing formed between the slider and the stator to guide the sliding path of the slider.

According to the present disclosure, the alignment stage may align the first wafer in the first axis direction, second axis direction, and theta axis direction using a second voice coil motor or a piezoelectric element.

According to the present disclosure, the alignment stage may include a stage jig, a flexure frame having a portion fixed to the stage jig and another portion elastically deformable with respect to the stage jig, and at least one second voice coil motor formed on the stage jig and configured to elastically deform the other portion of the flexure frame.

According to the present disclosure, the flexure frame may include a fixed portion fixed to the stage jig, a flexure hinge formed on the fixed portion and made of an elastic material, and a movable portion that supports the first wafer chuck and is precisely elastically displaced using the flexure hinge.

According to the present disclosure, the flexure frame may further include a serial amplification portion comprising at least one intermediate portion formed between the fixed portion and the movable portion, and at least one serial flexure hinge that connects these components in series, in order to amplify the stroke of the movable portion driven by the second voice coil motor.

According to the present disclosure, the flexure frame may further include a parallel amplification portion comprising at least one overlapping portion formed between the fixed portion and the movable portion, and at least one parallel flexure hinge that connects these components in parallel, in order to amplify the stroke of the movable portion driven by the second voice coil motor.

According to the present disclosure, the second voice coil motor may include a first-axis forward voice coil motor formed on one side of the movable portion and arranged in a forward direction along the first axis direction, a first-axis reverse voice coil motor formed on the opposite side of the movable portion and arranged in a reverse direction along the first axis direction, allowing the movable portion to be precisely moved along the first axis direction or precisely rotated about the theta axis, a second-axis forward voice coil motor formed on another side of the movable portion and arranged in a forward direction along the second axis direction, and a second-axis reverse voice coil motor formed on yet another side of the movable portion and arranged in a reverse direction along the second axis direction, allowing the movable portion to be precisely moved along the second axis direction or precisely rotated about the theta axis.

According to the present disclosure, the apparatus may further include a transfer device that moves the base portion forward and backward to a position corresponding to a second wafer chuck that holds the second wafer in place, so that the second wafer can be bonded to the first wafer.

According to the present disclosure, the apparatus may further include a first camera formed on the first wafer chuck or the alignment stage and configured to detect a second identifier of the second wafer, a measuring device configured to measure the vertical movement distance of the first wafer or the first wafer chuck, and a controller configured to receive an image signal from the first camera or a measurement signal from the measuring device, and to apply a control signal to at least one of the first driving device, the second driving device, the alignment stage, the transfer device, or any combination thereof.

According to the present disclosure, the controller may apply a first vertical movement control signal to the first driving device in a first wafer loading mode in which the first wafer is loaded onto the first wafer chuck and the first wafer chuck holds the first wafer, apply an alignment control signal to the alignment stage in an alignment mode in which the position-confirmed second wafer is used as a reference to precisely align the first wafer along the first axis direction, second axis direction, and theta axis direction, and apply a second vertical movement control signal to the second driving device in a bonding mode in which the aligned first wafer and second wafer are bonded.

Meanwhile, a wafer bonding apparatus using the multi-axis stage apparatus according to the concept of the present disclosure for solving the above problems may include (a) a step of transferring a second wafer to a position below a second wafer chuck using a second wafer transfer arm, picking up the second wafer by a picker of the second wafer chuck, bringing the second wafer into close contact with the second wafer chuck, and holding the contacted second wafer with the second wafer chuck, (b) a step of detecting the position of the second wafer using a first camera formed on the first wafer chuck or the alignment stage, (c) a step of coarsely moving the first wafer chuck vertically using the first driving device, loading the first wafer onto lift pins of the first wafer chuck by a first wafer transfer arm, lowering the lift pins, and holding the first wafer with the first wafer chuck, (d) a step of precisely aligning the first wafer in a first axis direction, a second axis direction, and a theta axis direction based on the position-confirmed second wafer, using a second camera formed on the second wafer chuck and the alignment stage, and (e) a step of precisely moving the first wafer chuck vertically using the second driving device and bonding the aligned first wafer and the second wafer.

Meanwhile, a wafer bonding apparatus according to the concept of the present disclosure for solving the above problems may include a second wafer chuck configured to hold a second wafer; a first wafer chuck configured to hold a first wafer; and a multi-axis stage apparatus configured to align the first wafer and to bond the aligned first wafer to the second wafer.

The multi-axis stage apparatus may include a base portion, a first driving device formed on the base portion and configured to vertically move at least a portion thereof in a third axis direction by a first distance with respect to the base portion, a second driving device formed on the first driving device and configured to vertically move at least a portion thereof in the third axis direction by a second distance with respect to the first driving device, and an alignment stage connected to the second driving device and configured to align the first wafer chuck holding the first wafer, the alignment stage allowing the first wafer to be vertically moved in the third axis direction by a distance equal to the sum of the first and second distances.

The first driving device may be configured to coarsely move the first wafer by the first distance, which is relatively longer than the second distance, and the second driving device may be configured to precisely move the first wafer by the second distance, which is relatively shorter than the first distance.

The first driving device may include a driving motor formed on the base portion and configured to rotate a screw shaft, and a movable frame in which a nut member is formed to move vertically by the rotation of the screw shaft.

The second driving device may include a plurality of first voice coil motors (VCMs) isometrically arranged around the nut member on the movable frame, a plurality of movable stages vertically moved with high precision by the first voice coil motors, and a plurality of flexure joints formed on the movable stages and providing multi-axis degrees of freedom.

The alignment stage may include a stage jig, a flexure frame having a fixed portion fixed to the stage jig and a deformable portion elastically deformable with respect to the stage jig, and at least one second voice coil motor formed on the stage jig and configured to elastically deform the deformable portion of the flexure frame.

According to various embodiments of the present disclosure as described above, with respect to vertical movement along the Z-axis, it is possible to significantly improve both the bonding precision and process speed by simultaneously employing a first driving device with a long stroke and low precision, and a second driving device with a short stroke and high precision. Furthermore, mechanical errors or component damage during multi-axis operation can be prevented by using voice coil motors and flexure joints. In addition, mechanical deformation or thermal deformation of components due to loading can be avoided, thereby significantly improving the productivity, durability, and reliability of the product. It should be noted, however, that the scope of the present disclosure is not limited by these effects.

### BRIEF DESCRIPTION OF THE DRAWINGS

The above and other features and advantages of the present invention will become more apparent by describing in detail embodiments thereof with reference to the attached drawings in which:

FIG. 1 is a side cross-sectional view illustrating a multi-axis stage apparatus according to some embodiments of the present disclosure.

FIG. 2 is an exploded perspective view illustrating the multi-axis stage apparatus of FIG. 1.

FIG. 3 is an exploded perspective view illustrating the alignment stage of the multi-axis stage apparatus shown in FIG. 2.

FIG. 4 is a conceptual diagram illustrating another example of a flexure frame of the alignment stage shown in FIG. 3.

FIG. 5 is a conceptual diagram illustrating yet another example of a flexure frame of the alignment stage shown in FIG. 3.

FIGS. 6 through 16 are cross-sectional views sequentially illustrating a wafer bonding process using the multi-axis stage apparatus shown in FIG. 1.

FIG. 17 is a flowchart illustrating a wafer bonding method using the multi-axis stage apparatus according to some embodiments of the present disclosure.

### DETAILED DESCRIPTION OF THE DISCLOSURE

Hereinafter, preferred embodiments of the present disclosure will be described in detail with reference to the accompanying drawings.

The embodiments of the present disclosure are provided to more fully describe the disclosure to those skilled in the art. These embodiments may be modified in various forms and are not intended to limit the scope of the disclosure to the specific embodiments described herein. Rather, these embodiments are provided to ensure thorough and complete disclosure of the present disclosure and to fully convey the spirit of the disclosure to those skilled in the art. In addition, the thicknesses and sizes of the individual layers or components shown in the drawings may be exaggerated for clarity and convenience of explanation.

The terminology used in the present disclosure is intended to describe specific embodiments and is not intended to limit the disclosure. As used in this specification, the singular forms may include the plural forms as well, unless the context clearly indicates otherwise. Furthermore, as used herein, the terms “comprise” and/or “comprising” specify the presence of stated features, numbers, steps, operations, members, elements, and/or groups thereof, but do not preclude the presence or addition of one or more other features, numbers, steps, operations, members, elements, and/or groups thereof.

Hereinafter, embodiments of the present disclosure will be described with reference to the drawings, which schematically illustrate ideal embodiments of the disclosure. In the drawings, for example, variations in illustrated shapes may be expected depending on manufacturing technologies and/or tolerances. Therefore, the embodiments of the inventive concept should not be construed as being limited to the specific shapes of regions illustrated in the drawings, and should be understood to include deviations in shape that may result from manufacturing processes.

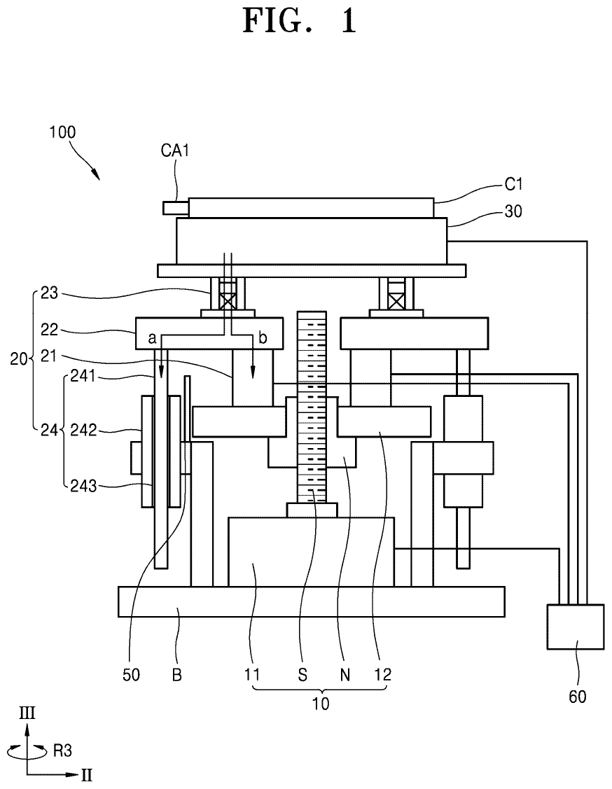

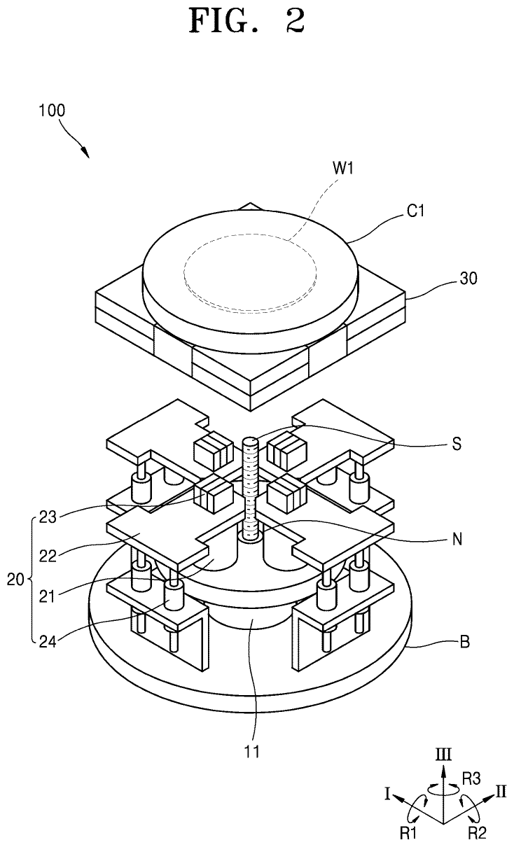

FIG. 1 is a side cross-sectional view illustrating a multi-axis stage apparatus 100 according to some embodiments of the present disclosure, and FIG. 2 is an exploded perspective view illustrating the multi-axis stage apparatus 100 of FIG. 1.

First, as shown in FIGS. 1 and 2, the multi-axis stage apparatus 100 according to some embodiments of the present disclosure may generally include a base portion B, a first driving device 10, a second driving device 20, and an alignment stage 30.

The base portion B serves, for example, as a support structure having sufficient strength and durability to support the first driving device 10, the second driving device 20, and the alignment stage 30, and to withstand the wafer bonding pressure. The base portion is not limited to the structures illustrated in the drawings, and may be implemented in various types and shapes of three-dimensional structures.

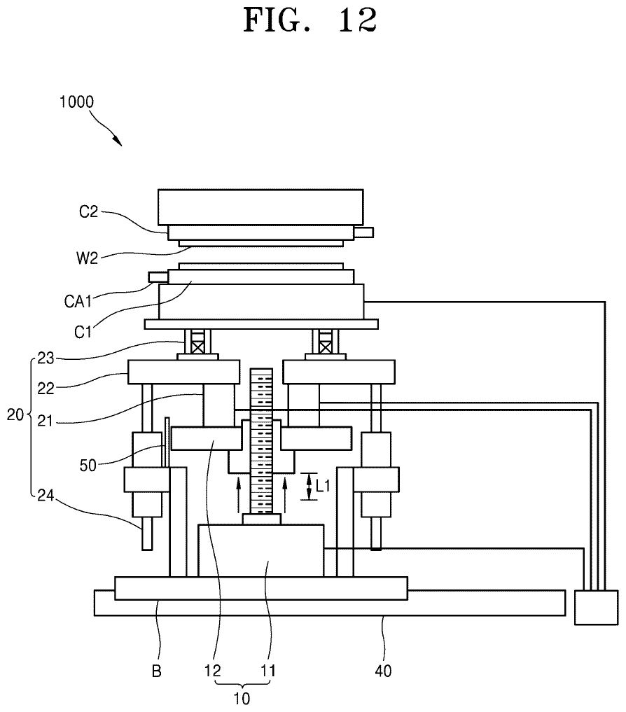

The first driving device 10 may be, for example, a type of primary vertical driving device formed on the base portion B, and configured to move at least a portion thereof in the third axis direction III by a first distance L1 (see FIG. 12), with respect to the base portion B.

Here, the third axis direction III refers to a vertical direction that is perpendicular to a plane spanning the first axis direction I and the second axis direction II (i.e., the horizontal plane). For example, the third axis direction III may correspond to the Z-axis direction in which the first wafer W1 moves up and down. In addition, the second axis direction II may correspond to the Y-axis direction, which is the main direction in which the first wafer W1 is loaded or unloaded, and the first axis direction I may correspond to the X-axis direction that is orthogonal to the second axis direction II. However, it should be understood that these axis directions I, II, and III are not limited to the orientations shown in the drawings, and any mutually orthogonal directions may be applied.

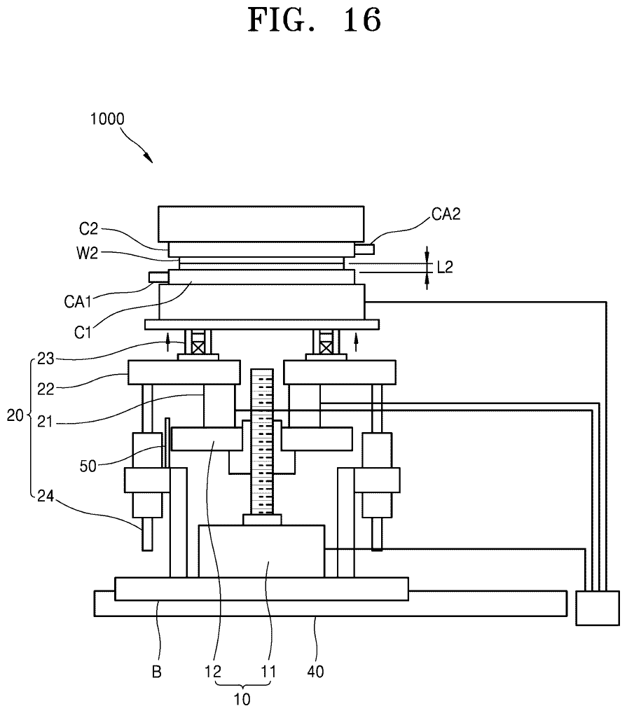

The second driving device 20 may be, for example, a type of secondary vertical driving device formed on the first driving device 10, and configured to move at least a portion thereof in the third axis direction III by a second distance L2 (see FIG. 16), with respect to the first driving device 10.

In this regard, the first driving device 10 may be configured to coarsely move the first wafer W1 by a first distance L1, which is relatively longer than the second distance L2. For example, the first driving device may be a relatively low-precision vertical driving system capable of moving the first wafer W1 with relatively low precision, such as on the order of micrometers or millimeters or greater, using a ball screw or a lead screw.

Also, the second driving device 20 is configured to precisely move the first wafer W1 up and down by a relatively short second distance L2 compared to the first distance L1. For example, it may be a relatively high-precision vertical drive system using a first voice coil motor VCM or a piezoelectric Piezo element, capable of moving the first wafer W1 up and down with sub-nanometer level accuracy.

Here, for mechanical explanation, for example, in the drawings, the second driving device 20 is illustrated as being connected above the first driving device 10, but it is also possible for the first driving device 10 to be formed above the second driving device 20.

The alignment stage 30 is, for example, connected to the second driving device 20 such that the first wafer W1 can be moved vertically in the third axis direction III by a distance equal to the sum of the first distance L1 and the second distance L2. It may be a type of alignment apparatus for aligning a first wafer chuck C1 that holds the first wafer W1. Here, the first wafer chuck C1 may be either a vacuum chuck or an electrostatic chuck.

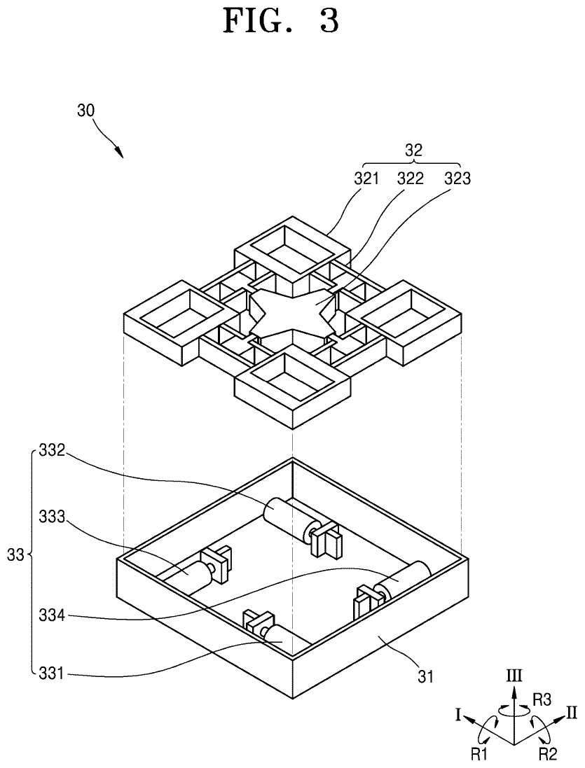

The alignment stage 30, for example, may align the first wafer W1 in the first axis direction I, second axis direction II, and theta-axis direction R3 using a second voice coil motor 33 (see FIG. 3), or a piezoelectric element.

Here, the theta-axis direction R3 may be a direction of rotation on the plane formed by the first axis direction I and the second axis direction II, with the third axis direction III as the axis of rotation. However, it is not limited to the illustrated directions, and various rotational directions may also be applied.

More specifically, as shown in FIGS. 1 and 2, the first driving device 10 may include a movable frame 12 formed on the base portion B, and comprising a driving motor 11 for rotating a screw shaft S and a nut member N that vertically moves along the screw by rotation of the screw shaft S.

Here, the driving motor 11, for example, may be a DD (Direct Drive) motor that directly drives the screw shaft S without a separate power transmission device or actuator, in order to enhance precision. In addition, various types of motors such as servo motors may also be applied as the driving motor 11.

Also, the movable frame 12 may be a circular or polygonal plate-shaped structure having the nut member N threadably engaged with the screw shaft S formed at a central portion thereof, such that the center of gravity can be uniformly applied.

Accordingly, in the first driving device 10, when the driving motor 11 rotates the screw shaft S forward or backward, the nut member N, which is threadably engaged with the screw shaft S, moves vertically up and down, thereby causing the movable frame 12 to move up or down. If necessary, the movable frame 12 may be guided along the vertical path by guide members such as guide rods or rail structures.

The second driving device 20 may include a plurality of first voice coil motors 21 (VCM) (four in the drawings) arranged equiangularly around a nut member N on a movable frame 12, as illustrated in FIGS. 1 and 2, a plurality of movable stages 22 (four in the drawings) that are precisely moved up and down by the first voice coil motors 21, and a plurality of flexure joints 23 (four in the drawings) formed on the movable stages 22, each having multi-axis degrees of freedom.

Here, the first voice coil motor 21 may be equiangularly arranged in a quadrangular configuration around the nut member N on the movable frame 12 such that the first wafer W1 can rotate in a first rotational axis direction R1 or a second rotational axis direction R2, thereby reducing the capacity and installation cost of the product while increasing the number of installations to distribute the load. However, such a quadrangular arrangement of the first voice coil motors 21 is not limited thereto; for example, triangular, pentagonal, or hexagonal arrangements in which the motors are equiangularly disposed around the nut member N on the movable frame 12 may also be applied.

The first rotational axis direction R1 may refer to a direction in which rotation occurs about a first axis I in a plane formed by a second axis II and a third axis III, while the second rotational axis direction R2 may refer to a direction in which rotation occurs about the second axis II in a plane formed by the first axis I and the third axis III. However, the first and second rotational axis directions R1 and R2 are not limited to those depicted in the drawings, and various rotational directions may be applied.

The voice coil motor (VCM) may be a type of linear motor based on the principle of a speaker, which induces extremely precise linear motion in proportion to the current flowing through a coil placed in the magnetic field of a permanent magnet.

However, the second driving device 20 of the present disclosure is not limited to using the first voice coil motor 21 and may alternatively employ various types of precision motors such as piezo motors utilizing piezoelectric elements.

The flexure joint 23, unlike a ball joint, may be a joint utilizing a leaf spring, a coil spring, or other complex three-dimensional spring hinges, and may be capable of sufficiently absorbing elastic deformation. Accordingly, mechanical errors and component damage can be prevented.

Therefore, by using the plurality of first voice coil motors 21, for example, when all of the first voice coil motors 21 are simultaneously extended or contracted, the alignment stage 30 can be moved with high precision in the third axis direction III. Alternatively, when at least one or more of the first voice coil motors 21 are differentially extended or contracted, the alignment stage 30 can be inclined and rotated in the first rotational axis direction R1 or the second rotational axis direction R2.

Meanwhile, the second driving device 20 may further include at least one load compensation device 24, which is formed between the base portion B and the movable stage 22 and is configured to distribute the load acting on the flexure joint 23 to prevent heat generation in the first voice coil motors 21.

More specifically, for example, the load compensation device 24 may utilize a magnetic force characteristic identical to that applied to the first voice coil motors 21. It may include a slider 241 formed on the outer side of the movable stage 22, at least a portion of which is made of a first magnetic material, a fixed member 242 fixed to the base portion B, at least a portion of which is made of a second magnetic material that attracts or repels the first magnetic material, and a guide bearing 243 formed between the slider 241 and the fixed member 242 to guide the sliding path of the slider 241.

Thus, as indicated by arrows “a” and “b” in FIG. 1, a portion of the load transferred to the flexure joint 23 can be redirected toward the load compensation device 24 via the direction of arrow “a,” thereby reducing the portion of the load delivered to the first voice coil motor 21 in the direction of arrow “b.” This minimizes heat generation in the first voice coil motor 21 caused by the load.

The load compensation device 24 is not limited to the illustrated magnetic-force-based method and may alternatively employ other types such as pneumatic cylinders, hydraulic cylinders, or coil springs.

FIG. 3 is an exploded perspective view showing the alignment stage 30 of the multi-axis stage apparatus 100 illustrated in FIG. 2.

As illustrated in FIGS. 1 to 3, the alignment stage 30 of the multi-axis stage apparatus 100 according to some embodiments of the present disclosure may be installed, for example, between the above-described base portion B, the first driving device 10, and the second driving device 20, or on the second driving device 20. The alignment stage 30 may include a stage jig 31, a flexure frame 32 having a portion fixed to the stage jig 31 and the other portion elastically deformable with respect to the stage jig 31, and at least one second voice coil motor 33 formed on the stage jig 31 and configured to elastically deform the other portion of the flexure frame 32.

More specifically, the flexure frame 32 may include a fixed portion 321 fixed to the stage jig 31, a flexure hinge 322 formed on the fixed portion 321 and made of an elastic material, and a movable portion 323 that supports the first wafer chuck C1 and is elastically displaced with high precision via the flexure hinge 322.

Here, the second voice coil motor 33 may include a total of four voice coil motors installed. These may include a first-axis forward-direction voice coil motor 331 formed on one side of the movable portion 323 and arranged in the forward direction along the first axis direction I, a first-axis reverse-direction voice coil motor 332 formed on the other side of the movable portion 323 and arranged in the reverse direction along the first axis direction I, allowing the movable portion 323 to move precisely in the first axis direction I or rotate precisely in the theta axis direction R3, a second-axis forward-direction voice coil motor 333 formed on another side of the movable portion 323 and arranged in the forward direction along the second axis direction II, and a second-axis reverse-direction voice coil motor 334 formed on yet another side of the movable portion 323 and arranged in the reverse direction along the second axis direction II, allowing the movable portion 323 to move precisely in the second axis direction II or rotate precisely in the theta axis direction R3.

Thus, for example, among the four second voice coil motors 33 installed on the stage jig 31, when the first-axis forward-direction voice coil motor 331 is extended while the first-axis reverse-direction voice coil motor 332 is simultaneously contracted, the movable portion 323 can be precisely moved in the first axis direction I. When both the first-axis forward-direction voice coil motor 331 and the first-axis reverse-direction voice coil motor 332 are extended simultaneously, the movable portion 323 can be precisely rotated in the theta axis direction R3. Based on the same principle, using the second-axis forward-direction voice coil motor 333 and the second-axis reverse-direction voice coil motor 334, the movable portion 323 can be precisely moved in the second axis direction II or rotated in the theta axis direction R3.

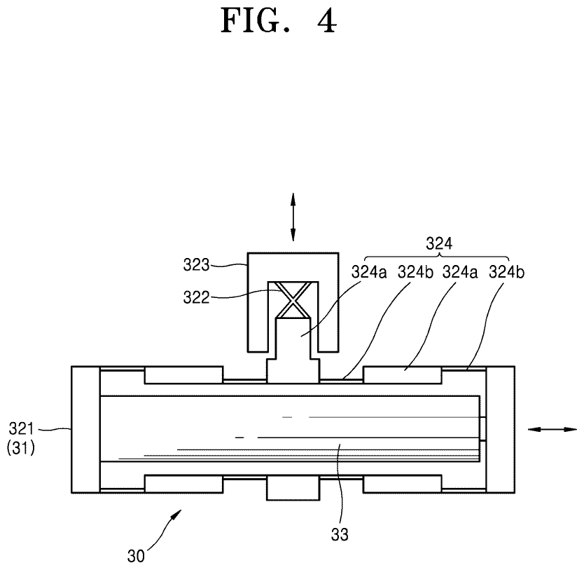

FIG. 4 is a conceptual diagram illustrating another example of the flexure frame 32 of the alignment stage 30 shown in FIG. 3.

As shown in FIGS. 3 and 4, the flexure frame 32 may further include a serial amplification unit 324 composed of at least one intermediate portion 324a formed between the fixed portion 321 and the movable portion 323, and at least one serial flexure hinge 324b that serially connects them, in order to amplify the stroke of the movable portion 323 by the second voice coil motor 33.

Therefore, as shown in FIG. 4, when the second voice coil motor 33 extends or contracts the opposite side with reference to the fixed portion 321, the stroke may be greatly amplified by the serial amplification unit 324, which consists of a plurality of intermediate portions 324a and a plurality of serial flexure hinges 324b connected in series. As a result, a large force or displacement can be obtained via the movable portion 323 with only a small force or displacement.

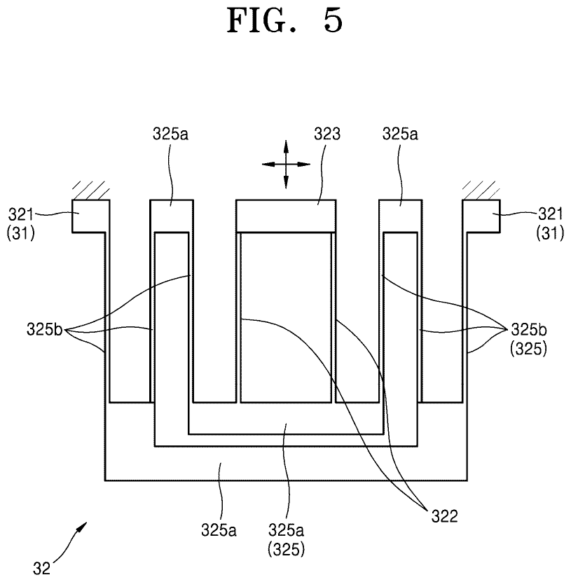

FIG. 5 is a conceptual diagram illustrating another example of the flexure frame 32 of the alignment stage 30 shown in FIG. 3.

As shown in FIGS. 3 and 5, the flexure frame 32 may further include a parallel amplification unit 325 for amplifying the stroke of the movable portion 323 by the second voice coil motor 33. The parallel amplification unit 325 may include at least one overlapping portion 325a formed between the fixed portion 321 and the movable portion 323, and at least one parallel flexure hinge 325b that connects them in parallel.

Therefore, as illustrated in FIG. 5, when an external force, such as from the second voice coil motor 33, acts on the overlapping portion 325a with respect to the fixed portion 321, the stroke may be significantly amplified by the parallel amplification unit 325, which consists of multiple overlapping portions 325a and multiple parallel flexure hinges 325b connected in parallel. As a result, a large force or displacement can be obtained via the movable portion 323 with only a small force or displacement, and the structural strength can also be enhanced.

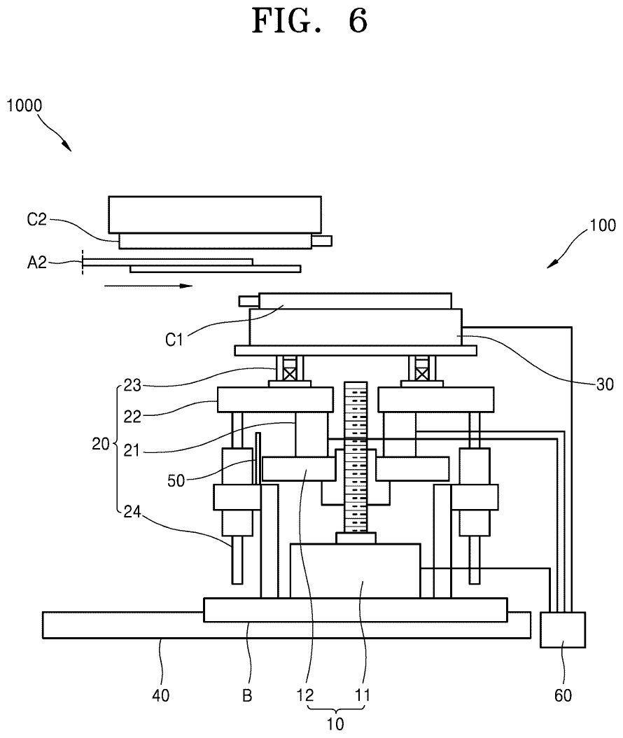

FIGS. 6 to 16 are cross-sectional views sequentially illustrating a wafer bonding process using the multi-axis stage apparatus 100 of FIG. 1.

As shown in FIGS. 1 and 6, the multi-axis stage apparatus 100 according to some embodiments of the present disclosure may further include a transfer unit 40 configured to move the base portion B back and forth to a position corresponding to a second wafer chuck C2 on which a second wafer W2 is held, in order to bond the second wafer W2 to the first wafer W1.

The multi-axis stage apparatus 100 according to some embodiments of the present disclosure may also include a first camera CA1 formed on the first wafer chuck C1 or the alignment stage 30 for detecting a second identifier M2 of the second wafer W2, a measurement device 50 such as an encoder for measuring the vertical displacement of the first wafer W1 or the first wafer chuck C1, and a controller 60 for receiving image signals from the first camera CA1 or measurement signals from the measurement device 50, and for outputting control signals to at least one of the first driving device 10, the second driving device 20, the alignment stage 30, the transfer unit 40, or any combination thereof.

Here, the measurement device 50 may utilize various encoders or sensors that convert the position or distance of an object into electrical signals. For example, a linear encoder capable of detecting angular deviations within a 0.5-degree range may be used.

Here, the controller 60 may include various control devices, such as microprocessors, central processing units, arithmetic units, input/output signal devices, storage devices in which programs are stored, personal computers, server computers, networks, smartphones, smart pads, smart devices, control boards, control chips, control components, and electronic components, and may be configured to apply a primary vertical motion control signal to the first driving device 10 in a first wafer loading mode in which the first wafer W1 is loaded onto the first wafer chuck C1 and the first wafer chuck C1 holds the first wafer W1, apply an alignment control signal to the alignment stage 30 in an alignment mode in which the first wafer W1 is precisely aligned with the second wafer W2 in the first axis direction I, the second axis direction II, and the theta axis direction R3 based on the position of the second wafer W2, and apply a secondary vertical motion control signal to the second driving device 20 in a bonding mode in which the aligned first wafer W1 and second wafer W2 are bonded together.

Meanwhile, as shown in FIG. 6, a wafer bonding apparatus 1000 including the multi-axis stage apparatus 100 according to some embodiments of the present disclosure may include a second wafer chuck C2 that holds the second wafer W2 and is fixed above, a first wafer chuck C1 that holds the first wafer W1 and is installed below in a vertically movable manner, and the above-described multi-axis stage apparatus 100, which supports the first wafer W1, aligns it into a precise position, and bonds the first wafer W1 to the second wafer W2.

Here, the second wafer chuck C2 may be a vacuum chuck or an electrostatic chuck.

Additionally, the multi-axis stage apparatus 100 may be the same in configuration and function as the multi-axis stage apparatus 100 illustrated in FIGS. 1 to 5, and thus detailed descriptions thereof will be omitted.

Accordingly, as shown in FIGS. 6 through 16, a sequential explanation of the operation process of the wafer bonding apparatus 1000 according to some embodiments of the present disclosure is as follows. First, as illustrated in FIG. 6, the second wafer transfer arm A2 may transfer the second wafer W2 to a position below the second wafer chuck C2. At this time, the second wafer transfer arm A2 may load the second wafer W2 by vacuum-adsorbing a portion of the rear surface of the inverted second wafer W2 or by clamping the side edge of the second wafer W2.

At this time, to secure sufficient loading space for the second wafer W2, the first driving device 10 may descend with a relatively long stroke and remain in a standby state.

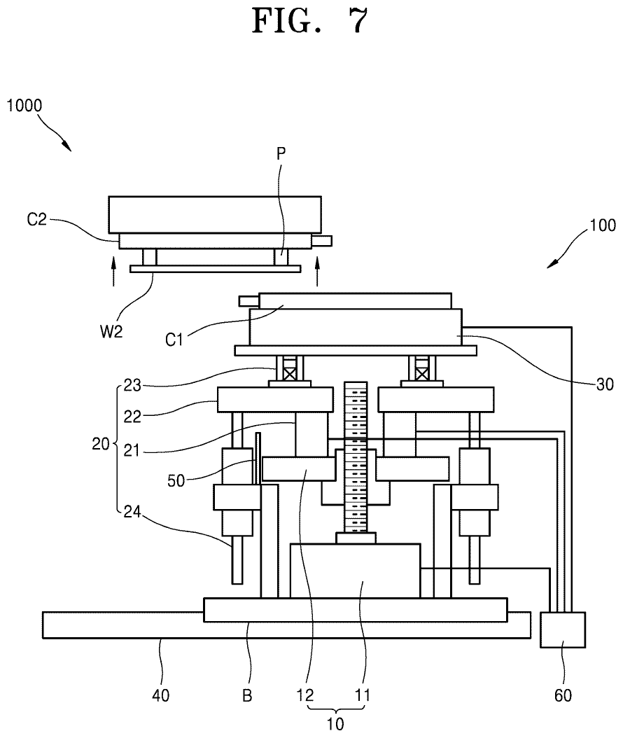

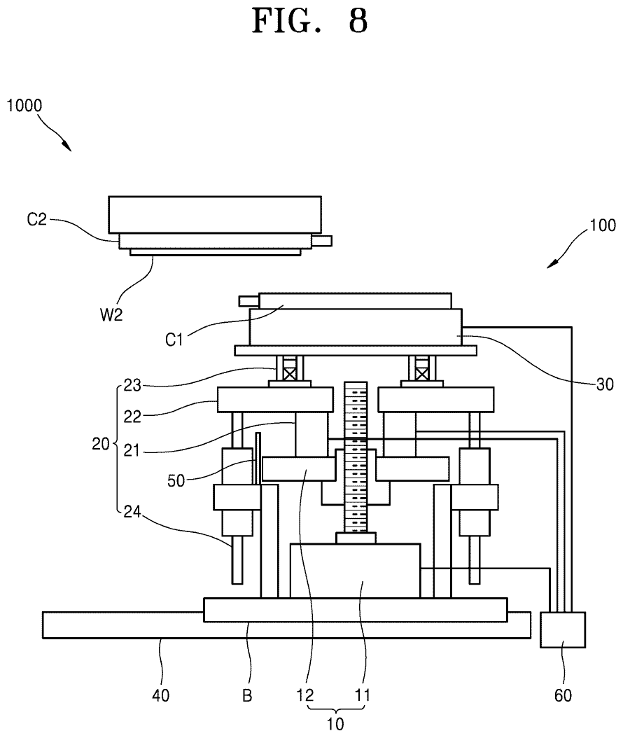

Subsequently, as illustrated in FIG. 7, the picker P of the second wafer chuck C2 picks up the second wafer W2 and ascends to bring the second wafer W2 into close contact with the second wafer chuck C2. Then, as shown in FIG. 8, the second wafer chuck C2 vacuum-adsorbs the contacted second wafer W2 to perform chucking. Here, the picker P may not only vacuum-adsorb the rear surface of the second wafer W2, but may also adopt various other methods such as clamping the side of the second wafer W2.

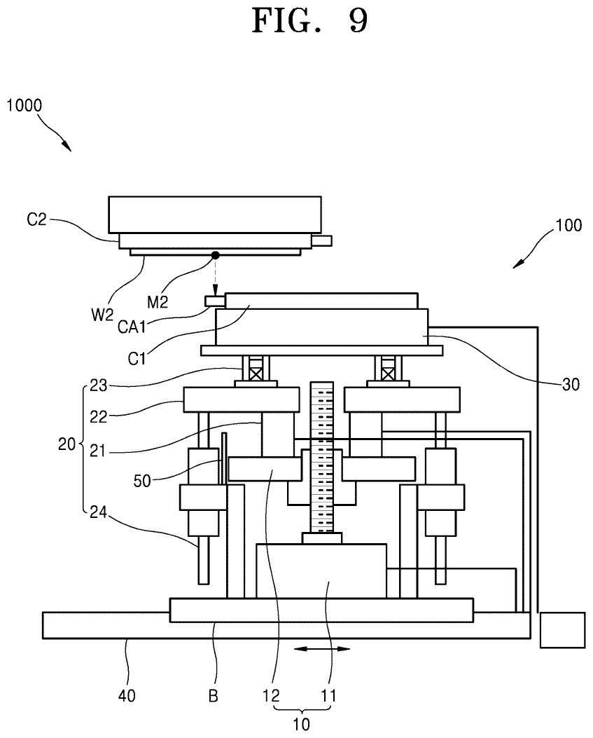

Subsequently, as illustrated in FIG. 9, the position of the second identifier M2 of the second wafer W2 vacuum-adsorbed by the second wafer chuck C2 may be detected using the first camera CA1 formed on the first wafer chuck C1 or the alignment stage 30. The second identifier M2 may include not only a separate identifier formed along the edge of the second wafer W2 but also various types of patterns formed on the front surface of the second wafer W2.

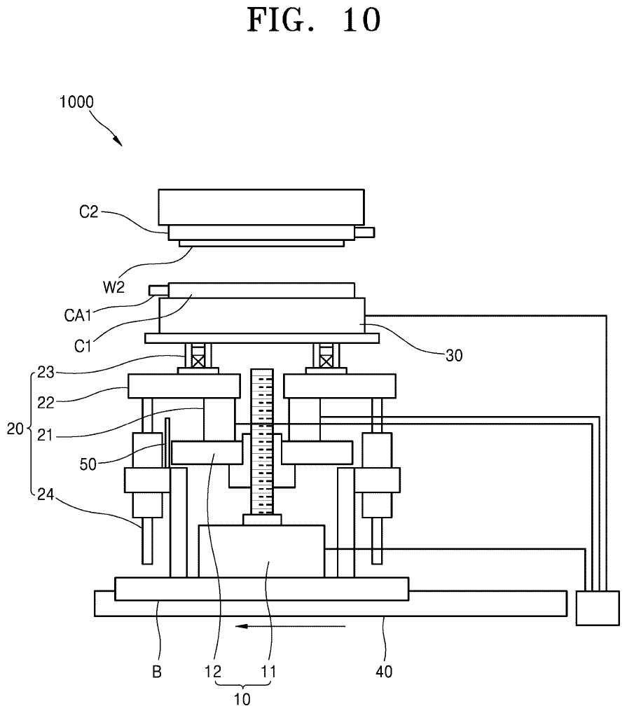

Subsequently, as shown in FIG. 10, the base portion B may be transported along the second axis direction II to a position corresponding to a second wafer chuck C2, which holds the second wafer W2, by using a transfer device 40.

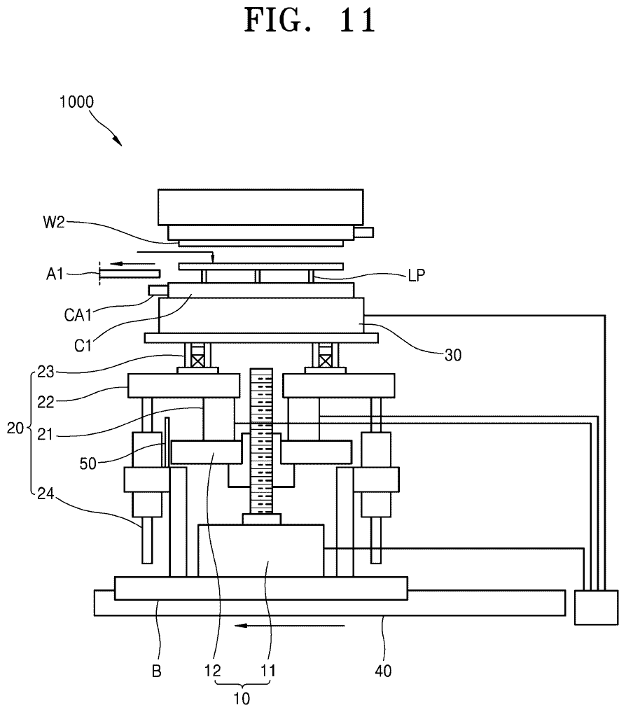

Then, as illustrated in FIG. 11, the first wafer transfer arm A1 may load the first wafer W1 onto lift pins LP of the first wafer chuck C1. At this time, the first wafer transfer arm A1 may support the rear side of the first wafer W1, approach above the lift pins LP, and descend to a height lower than the top ends of the lift pins LP to transfer the first wafer W1 onto the lift pins LP.

Subsequently, as shown in FIG. 12, the lift pins LP are lowered, allowing the first wafer chuck C1 to hold the first wafer W1 by vacuum suction. The first wafer chuck C1 may then be raised by approximately the first distance L1 using the first driving device (10).

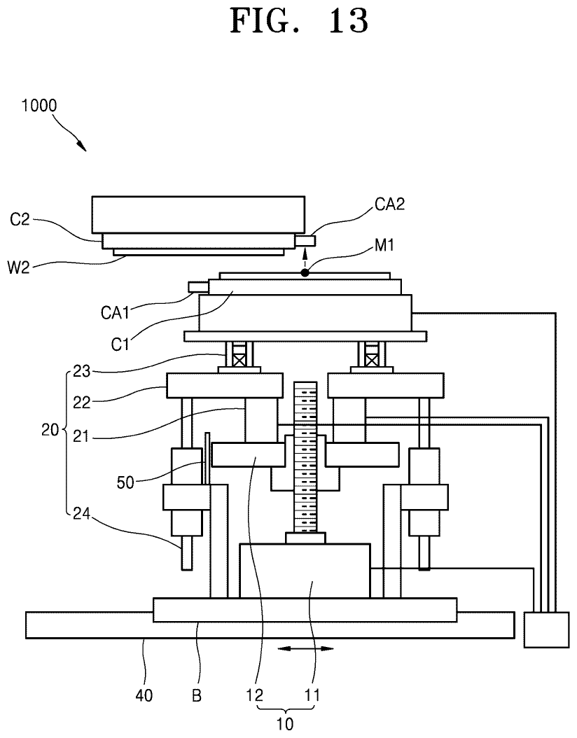

As shown in FIG. 13, the position of the first identifier M1 of the first wafer W1 may be detected by a second camera CA2 formed on the second wafer chuck C2. Then, using the alignment stage 30, the first wafer W1 may be precisely aligned with the already positioned second wafer W2 in the first axis direction I, the second axis direction II, and the theta axis direction R3.

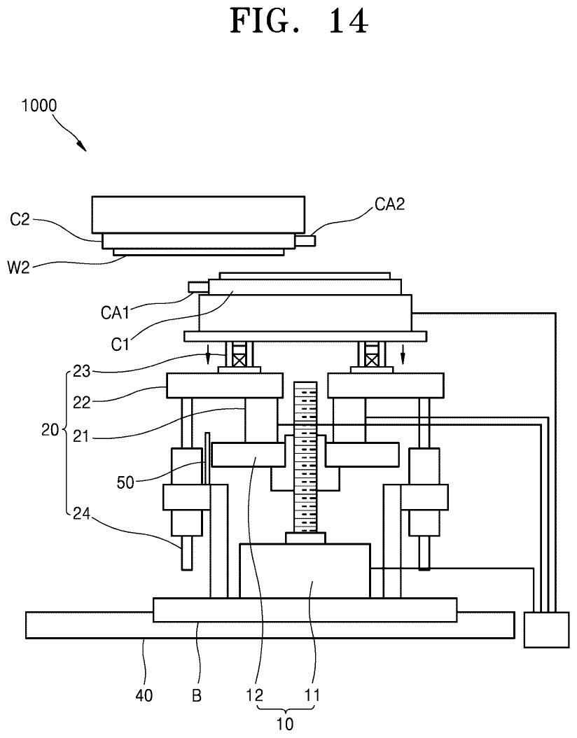

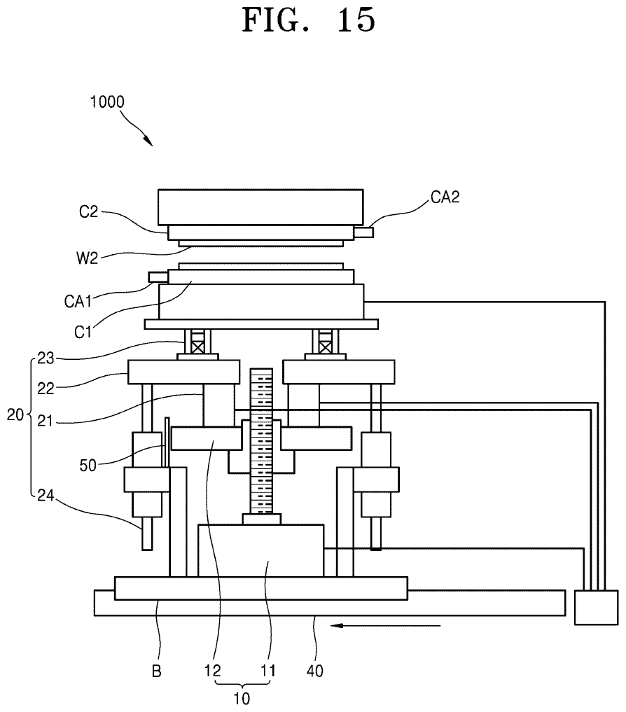

Subsequently, as shown in FIG. 14, the first wafer chuck C1 may be precisely lowered using the second driving device 20. Then, as shown in FIG. 15, the base portion B may be transported along the second axis direction II to a position corresponding to a second wafer chuck C2, which holds the second wafer W2, by using the transfer device 40. Next, as shown in FIG. 16, the first wafer chuck C1 may be precisely raised by the second distance L2 using the second driving device 20, thereby bonding the aligned first wafer W1 to the second wafer W2. Here, the second distance L2 is significantly shorter than the first distance L1, and may be exaggerated or emphasized in the drawing for the sake of descriptive clarity.

Accordingly, according to the multi-axis stage apparatus 100 and the wafer bonding apparatus 1000 of some embodiments of the present disclosure, both the bonding precision and the process speed can be significantly improved by employing, in combination, a first driving device 10 having a long stroke but low precision and a second driving device 20 having a short stroke but high precision for vertical movement along the Z-axis. For example, while the conventional repeatability precision was approximately ±100 nanometers, in the case of the present disclosure, the repeatability precision can be significantly improved to approximately ±5 nanometers.

In addition, according to the present disclosure, mechanical errors or component damage during multi-axis driving can be prevented by using components such as the first voice coil motor 21 and the flexure joints 23, and mechanical or thermal deformation caused by load can be prevented by employing a load compensation device 24, thereby significantly enhancing the productivity, durability, and reliability of the product.

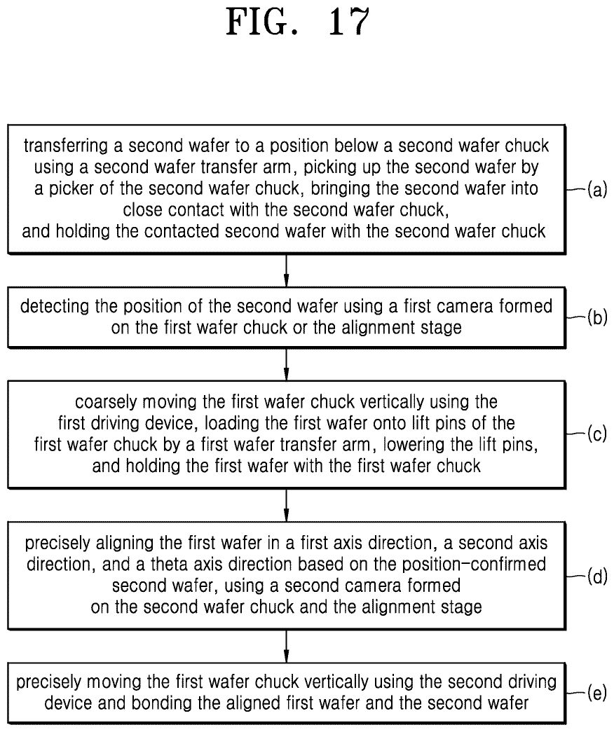

FIG. 17 is a flowchart illustrating a wafer bonding method using the multi-axis stage apparatus 100 according to some embodiments of the present disclosure.

As illustrated in FIGS. 1 to 17, the wafer bonding method using the multi-axis stage apparatus 100 according to some embodiments of the present disclosure may include (a) a step of transferring the second wafer W2 to a position below a second wafer chuck C2 using a second wafer transfer arm A2, picking up the second wafer W2 by a picker P of the second wafer chuck C2, bringing the second wafer W2 into close contact with the second wafer chuck C2, and holding the contacted second wafer W2 by vacuum suction using the second wafer chuck C2, (b) a step of detecting the position of a second identifier M2 of the second wafer W2 using a first camera CA1 formed on the first wafer chuck C1 or the alignment stage 30, (c) a step of coarsely moving the first wafer chuck C1 vertically using the first driving device 10, loading the first wafer W1 onto lift pins LP of the first wafer chuck C1 using a first wafer transfer arm A1, lowering the lift pins LP, and holding the first wafer W1 by vacuum suction using the first wafer chuck C1, (d) a step of precisely aligning the first wafer W1 in the first axis direction I, second axis direction II, and theta axis direction R3 with respect to the position-confirmed second wafer W2, using a second camera CA2 formed on the second wafer chuck C2 for detecting a first identifier M1 of the first wafer W2, and the alignment stage 30, and (e) a step of bonding the aligned first wafer W1 and second wafer W2 while precisely moving the first wafer chuck C1 vertically using the second driving device 20.

Although the present disclosure has been described with reference to the embodiments illustrated in the drawings, such embodiments are provided for illustrative purposes only. It will be understood by those skilled in the art that various modifications and equivalent embodiments can be made based on the present disclosure. Therefore, the true scope of technical protection of the present disclosure should be defined by the technical spirit of the appended claims.

1. A multi-axis stage apparatus comprising:
a base portion;
a first driving device formed on the base portion and configured to vertically move at least a portion thereof in a third axis direction by a first distance with respect to the base portion;
a second driving device formed on the first driving device and configured to vertically move at least a portion thereof in the third axis direction by a second distance with respect to the first driving device; and
an alignment stage connected to the second driving device so as to allow a first wafer to be vertically moved in the third axis direction by a distance equal to the sum of the first distance and the second distance, and configured to align a first wafer chuck holding the first wafer.

2. The multi-axis stage apparatus of claim 1, wherein the first driving device is configured to coarsely move the first wafer by the first distance, which is longer than the second distance, and wherein the second driving device is configured to precisely move the first wafer by the second distance, which is shorter than the first distance.

3. The multi-axis stage apparatus of claim 2, wherein the first driving device is configured to vertically move the first wafer with low precision on the order of micrometers or millimeters or greater using a ball screw or a lead screw, and wherein the second driving device is configured to vertically move the first wafer with high precision on the order of nanometers or less using a first voice coil motor or a piezoelectric element.

4. The multi-axis stage apparatus of claim 1, wherein the first driving device comprises
a driving motor formed on the base portion and configured to rotate a screw shaft; and
a movable frame in which a nut member is formed to move vertically by the rotation of the screw shaft.

5. The multi-axis stage apparatus of claim 4, wherein the driving motor is a direct drive motor configured to directly drive the screw shaft, and wherein the movable frame has the nut member threadably engaged with the screw shaft at a central portion thereof.

6. The multi-axis stage apparatus of claim 5, wherein the second driving device comprises:
a plurality of first voice coil motors isometrically arranged around the nut member on the movable frame;
a plurality of movable stages vertically moved with high precision by the first voice coil motors; and
a plurality of flexure joints formed on the movable stages and providing multi-axis degrees of freedom.

7. The multi-axis stage apparatus of claim 6, wherein the first voice coil motors are arranged in a quadrilateral or triangular configuration around the nut member on the movable frame, such that the first wafer is rotatable about a first rotational axis or a second rotational axis.

8. The multi-axis stage apparatus of claim 6, wherein the second driving device further comprises at least one load compensation device formed between the base portion and the movable stages, and configured to disperse loads acting on the flexure joints so as to prevent heat generation in the first voice coil motors.

9. The multi-axis stage apparatus of claim 8, wherein the load compensation device comprises:
a slider formed on an outer portion of the movable stage and at least partially composed of a first magnetic material;
a stator fixed to the base portion and at least partially composed of a second magnetic material, which interacts with the first magnetic material by attractive or repulsive force; and
a guide bearing formed between the slider and the stator and configured to guide a sliding path of the slider.

10. The multi-axis stage apparatus of claim 1, wherein the alignment stage is configured to align the first wafer in a first axis direction, a second axis direction, and a theta axis direction using a second voice coil motor or a piezoelectric element.

11. The multi-axis stage apparatus of claim 10, wherein the alignment stage comprises:
a stage jig;
a flexure frame having a portion fixed to the stage jig and another portion elastically deformable with respect to the stage jig; and
at least one second voice coil motor formed on the stage jig and configured to elastically deform the deformable portion of the flexure frame.

12. The multi-axis stage apparatus of claim 11, wherein the flexure frame comprises:
a fixed portion fixed to the stage jig;
a flexure hinge formed on the fixed portion and made of an elastic material; and
a movable portion configured to support the first wafer chuck and to be elastically displaced with high precision using the flexure hinge.

13. The multi-axis stage apparatus of claim 12, wherein the flexure frame further comprises a serial amplification portion including at least one intermediate portion formed between the fixed portion and the movable portion, and at least one serial flexure hinge connecting the intermediate portion and the movable portion in series, to amplify the stroke of the movable portion driven by the second voice coil motor.

14. The multi-axis stage apparatus of claim 12, wherein the flexure frame further comprises a parallel amplification portion including at least one overlapping portion formed between the fixed portion and the movable portion, and at least one parallel flexure hinge connecting the overlapping portion and the movable portion in parallel, to amplify the stroke of the movable portion driven by the second voice coil motor.

15. The multi-axis stage apparatus of claim 11, wherein the second voice coil motor comprises:
a first-axis forward voice coil motor formed on one side of the movable portion and arranged in a forward direction along a first axis direction;
a first-axis reverse voice coil motor formed on the opposite side of the movable portion and arranged in a reverse direction along the first axis direction, allowing the movable portion to move precisely in the first axis direction or rotate precisely in a theta axis direction;
a second-axis forward voice coil motor formed on another side of the movable portion and arranged in a forward direction along a second axis direction; and
a second-axis reverse voice coil motor formed on yet another side of the movable portion and arranged in a reverse direction along the second axis direction, allowing the movable portion to move precisely in the second axis direction or rotate precisely in the theta axis direction.

16. The multi-axis stage apparatus of claim 1, further comprising a transfer device configured to move the base portion forward and backward to a position corresponding to a second wafer chuck that holds a second wafer, so that the second wafer can be bonded to the first wafer.

17. The multi-axis stage apparatus of claim 16, further comprising a first camera formed on the first wafer chuck or the alignment stage and configured to detect a second identifier of the second wafer;
a measurement device configured to measure a vertical movement distance of the first wafer or the first wafer chuck; and
a controller configured to receive image signals from the first camera or measurement signals from the measurement device, and to apply control signals to at least one of the first driving device, the second driving device, the alignment stage, the transfer device, or any combination thereof.

18. The multi-axis stage apparatus of claim 17, wherein the controller is configured to
apply a first vertical motion control signal to the first driving device in a first wafer loading mode in which the first wafer is loaded onto the first wafer chuck and the first wafer chuck holds the first wafer;
apply an alignment control signal to the alignment stage in an alignment mode in which the first wafer is precisely aligned in a first axis direction, a second axis direction, and a theta axis direction based on the position-confirmed second wafer; and
apply a second vertical motion control signal to the second driving device in a bonding mode in which the aligned first wafer and the second wafer are bonded.

19. (canceled)

20. A wafer bonding apparatus comprising:
a second wafer chuck configured to hold a second wafer;
a first wafer chuck configured to hold a first wafer; and a multi-axis stage apparatus configured to align the first wafer and bond the aligned first wafer to the second wafer,
wherein the multi-axis stage apparatus comprises:
a base portion;
a first driving device formed on the base portion and configured to vertically move at least a portion thereof in a third axis direction by a first distance with respect to the base portion;
a second driving device formed on the first driving device and configured to vertically move at least a portion thereof in the third axis direction by a second distance with respect to the first driving device; and
an alignment stage connected to the second driving device and configured to align the first wafer chuck holding the first wafer, such that the first wafer can be vertically moved in the third axis direction by a distance equal to the sum of the first distance and the second distance, wherein the first driving device is configured to coarsely move the first wafer by the first distance, which is longer than the second distance,
wherein the second driving device is configured to precisely move the first wafer by the second distance, which is shorter than the first distance,
wherein the first driving device comprises:
a driving motor formed on the base portion and configured to rotate a screw shaft; and
a movable frame in which a nut member is formed to move vertically by the rotation of the screw shaft,
wherein the second driving device comprises:
a plurality of first voice coil motors isometrically arranged around the nut member on the movable frame;
a plurality of movable stages vertically moved with high precision by the first voice coil motors; and
a plurality of flexure joints formed on the movable stages and providing multi-axis degrees of freedom, and
wherein the alignment stage comprises:
a stage jig;
a flexure frame having a portion fixed to the stage jig and another portion elastically deformable with respect to the stage jig; and
at least one second voice coil motor formed on the stage jig and configured to elastically deform the other portion of the flexure frame.
